(19) United States
(12) Patent Application Publication
(10) Pub. No.: US 2025/0349730 A1
(43) Pub. Date: Nov. 13, 2025

(54) SEMICONDUCTOR PACKAGE HAVING AN INTERPOSER SUBSTRATE

(71) Applicant: SAMSUNG ELECTRONICS CO., LTD., SUWON-SI (KR)

(72) Inventor: Gitae PARK, Suwon-si (KR)

(21) Appl. No.: 18/970,805

(22) Filed: Dec. 5, 2024

(30) Foreign Application Priority Data
May 9, 2024 (KR) 10-2024-0061281

(51) Int. Cl. H01L 23/538; H01L 23/13; H01L 23/31; H01L 25/00; H01L 25/065

(52) U.S. Cl. CPC H01L 23/5385; H01L 23/13; H01L 23/3107; H01L 25/0655; H01L 25/50

(57) ABSTRACT

A semiconductor package including a lower substrate, a first lower semiconductor chip disposed on the lower substrate and a second lower semiconductor chip disposed adjacent to the first lower semiconductor chip on the lower substrate, and an interposer substrate including a first lower part surface disposed above and spaced apart from the first lower semiconductor chip and the second lower semiconductor chip, wherein a height of an upper surface of the first lower semiconductor chip is higher than a height of an upper surface of the second lower semiconductor chip, and a height difference between the upper surface of the first lower semiconductor chip and the first lower part surface of the interposer substrate is greater than a height difference between the upper surface of the first lower semiconductor chip and the second lower part surface of the interposer substrate.

### CROSS-REFERENCE TO RELATED APPLICATION(S)

This application claims priority under 35 U.S.C. § 119 to Korean Patent Application No. 10-2024-0061281, filed on May 9, 2024, in the Korean Intellectual Property Office, the disclosure of which is herein incorporated by reference.

### BACKGROUND

### 1. Technical Field

The present disclosure relates to a semiconductor package, and more particularly to a semiconductor package including an interposer substrate having multiple lower part surfaces.

### 2. Discussion of Related Art

A semiconductor package may include one or more integrated circuit chips disposed in an appropriate form to be used in an electronic product. A package-on-package structure may be used to reduce an area of the semiconductor package while maintaining a volume for components.

In a semiconductor package having a package-on-package structure, a semiconductor chip may be mounted on a printed circuit board (PCB), an interposer substrate may be connected to an upper side of the semiconductor chip, and a molding layer may be formed around the semiconductor chip by injecting and curing a fluid molding material.

FIG. 1 is a top plan diagram illustrating a molding material (MD) covering upper surfaces of a plurality of semiconductor chips LC and HC in a semiconductor package having a package-on-package structure.

When a thicknesses of the semiconductor chips HC and LC are different, a flow speed of a molding material MD may change with an interval between an interposer substrate and the semiconductor chips HC and LC. For example, a flow speed V1 of the molding material MD may be relatively fast at a relatively wide interval between the thinner semiconductor chip LC and the interposer substrate as compared to a flow speed V2 of the molding material MD at a relatively narrow interval between the thicker semiconductor chip HC and the interposer substrate. Due to changes in the flow speed of the molding material MD, the molding material MD may not be completely injected and a void may be formed.

### SUMMARY

An aspect of the present disclosure provides a semiconductor package for inhibiting or preventing a void from occurring in a molding layer on an upper surface of a semiconductor chip.

Another aspect also provides a semiconductor package for increasing heat dissipation efficiency.

According to an aspect, there is provided a semiconductor package including a lower substrate, a first lower semiconductor chip disposed on the lower substrate, a second lower semiconductor chip disposed adjacent to the first lower semiconductor chip on the lower substrate, and an interposer substrate including a first lower part surface disposed above and spaced apart from the first lower semiconductor chip and a second lower part surface disposed above and spaced apart from the second lower semiconductor chip, and a height of an upper surface of the first lower semiconductor chip is higher than a height of an upper surface of the second lower semiconductor chip, and a height difference between the upper surface of the first lower semiconductor chip and the first lower part surface of the interposer substrate is greater than a height difference between the upper surface of the first lower semiconductor chip and the second lower part surface of the interposer substrate.

According to an aspect, there is provided a semiconductor package including a lower substrate including a lower wiring structure, a first lower semiconductor chip disposed on the lower substrate, a second lower semiconductor chip disposed adjacent to the first lower semiconductor chip on the lower substrate and having a thickness thinner than that of the first lower semiconductor chip, an interposer substrate disposed above the first lower semiconductor chip and the second lower semiconductor chip, and a molding layer covering the first lower semiconductor chip and the second lower semiconductor chip, and the interposer substrate includes a first lower part surface facing the first lower semiconductor chip and spaced apart at a first interval from the lower substrate, and a second lower part surface facing the second lower semiconductor chip and spaced apart from the lower substrate at a second interval smaller than the first interval.

According to an aspect, there is provided a semiconductor package including a lower substrate including a lower wiring structure, a first lower semiconductor chip disposed on the lower substrate, a second lower semiconductor chip disposed on the lower substrate adjacent to the first lower semiconductor chip in a first direction parallel to a surface of the lower substrate, an interposer substrate disposed above the first lower semiconductor chip and the second lower semiconductor chip and including a lower part surface facing the lower substrate and an upper part surface that is a surface opposite to the lower part surface, and a molding layer disposed between the lower substrate and the interposer substrate, and the first lower semiconductor chip and the second lower semiconductor chip have different heights in a second direction perpendicular to the surface of the lower substrate, and a thickness of the interposer substrate at a first position overlapping the first lower semiconductor chip is thinner than a thickness between the upper part surface and the second lower part surface of the interposer substrate at a second position overlapping the second lower semiconductor chip.

Additional aspects of example embodiments will be set forth in part in the following description.

According to example embodiments, it is possible to implement a semiconductor package for inhibiting or preventing a void from occurring in a molding layer on an upper surface of a semiconductor chip.

According to example embodiments, it is possible to provide a semiconductor package for increasing heat dissipation efficiency.

Effects of the present disclosure are not limited to those described above and may vary within the scope of the technical spirit and extent of the present disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a top plan diagram illustrating that a molding material covers an upper surface of a semiconductor chip while flowing in a related semiconductor package;

FIG. 2 is a layout diagram illustrating a semiconductor package according to an example embodiment;

FIG. 3 is an exemplary cross-sectional diagram taken along line I-I′ of FIG. 2;

FIG. 4 is an exploded diagram illustrating part A of FIG. 3;

FIG. 5 is an exemplary cross-sectional diagram illustrating a semiconductor package according to another example embodiment;

FIG. 6 is an exploded diagram illustrating part B of FIG. 5;

FIG. 7 is an exemplary cross-sectional diagram illustrating a semiconductor package according to another example embodiment;

FIG. 8 is an exemplary cross-sectional diagram illustrating a semiconductor package according to another example embodiment;

FIGS. 9 to 13 are cross-sectional diagrams illustrating a manufacturing process a semiconductor package according to an example embodiment.

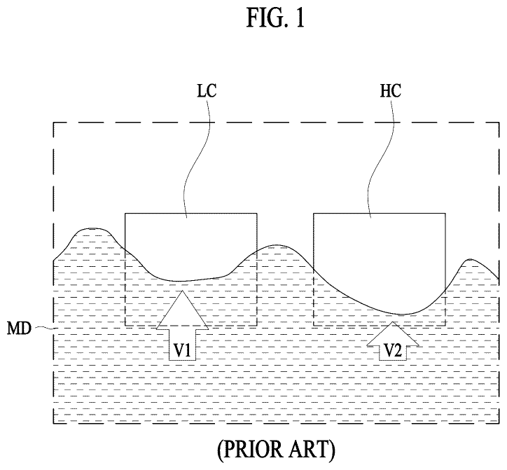

### DETAILED DESCRIPTION

Hereinafter, embodiments of the present disclosure are described clearly and in detail such that those skilled in the art may easily reproduce the present disclosure. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts.

Terms or words used in the present disclosure and the accompanying claims are not to be limited to general definitions or dictionary definitions. The terms and words are to be construed under a principle that an inventor may appropriately define a concept of a term in order to describe their invention. Thus, example embodiments do not represent all of the technical spirit of the present disclosure, and it should be understood that various equivalents and modifications that may replace the example embodiments and configurations may be present at the time of filing the application of the present disclosure.

In the following descriptions, terms in a singular form include terms a plural form unless an apparently and contextually conflicting description is present. Terms such as “including” or “comprising” may be used to indicate that a feature, a number, an operation, an action, an element, a component, or a combination thereof is present. It should be understood that the terms may not exclude a possibility that one or more other features, numbers, operations, actions, elements, components, or combinations thereof may be present or added.

In addition, it should be noted that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Hereinafter, a semiconductor according to the example embodiments will be described with reference to the drawings. The same reference numerals are used for the same components in the drawings, and redundant descriptions of the same components may be omitted.

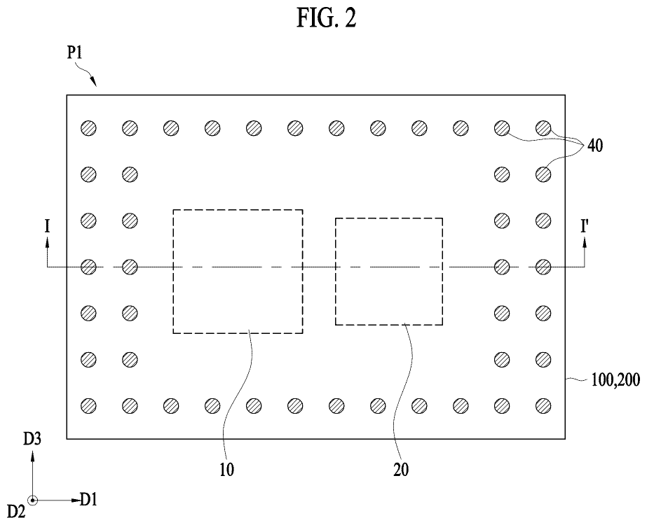

FIG. 2 is a layout diagram illustrating a semiconductor package Pl according to an example embodiment.

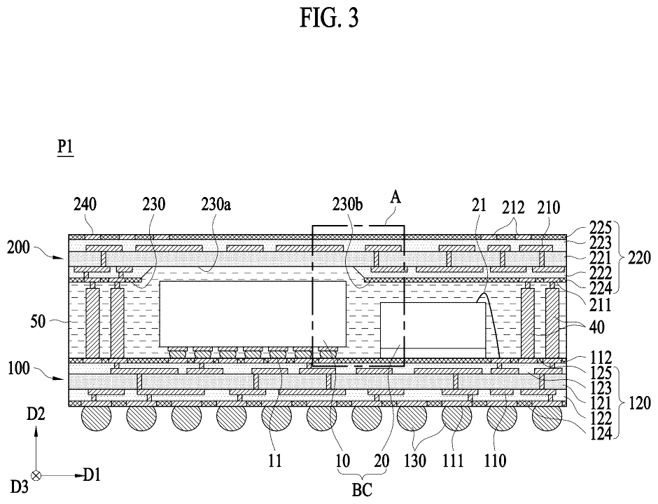

FIG. 3 is an exemplary cross-sectional diagram taken along line I-I′ of FIG. 2.

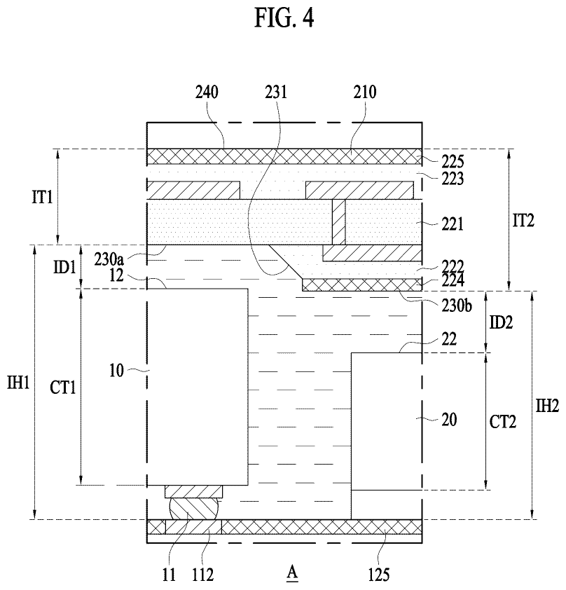

FIG. 4 is an exploded diagram illustrating part A of FIG. 3.

Referring to FIG. 2, FIG. 3, and FIG. 4, the semiconductor package P1 according to example embodiments may include a lower substrate 100, a first lower semiconductor chip 10, and a second lower semiconductor chip 20. The first lower semiconductor chip 10 and the second lower semiconductor chip 20 may be disposed on the lower substrate 100. The semiconductor package P1 may further include an interposer substrate 200, and a plurality of connectors 40. Each connector of the plurality of connectors 40 may electrically connect the lower substrate 100 and the interposer substrate 200.

In example embodiments, the lower substrate 100 may be a substrate for a package. For example, the lower substrate 100 may include a printed circuit board (PCB), a ceramic substrate, or a substrate for a wafer level package manufactured at a wafer level.

In example embodiments, the lower substrate 100 may include a first insulation layer 120, a first wiring structure 110, a first lower pad 111, and a first upper pad 112. Each of the first insulation layer 120, the first wiring structure 110, the first lower pad 111, and the first upper pad 112 may be disposed in the first insulation layer 120.

In example embodiments, the first insulation layer 120 of the lower substrate 100 and the first wiring structure 110 in the first insulation layer 120 may form a wiring pattern electrically connecting the first lower pad 111 and the first upper pad 112. The first wiring structure 110 may be a lower wiring structure.

In example embodiments, the first insulation layer 120 may include one or more layers. For example, the first insulation layer 120 may have a structure in which a first lower insulation layer 122 and a first lower passivation film 124 are stacked on a lower surface of a core layer 121, and in which a first upper insulation layer 123 and a first upper passivation film 125 are stacked on an upper surface of the core layer 121.

In example embodiments, each layer forming the first insulation layer 120 may include an insulating resin. The insulating resin may include a thermoset resin such as an epoxy resin, a thermoplastic resin such as polyimide, or such resins in which an inorganic filler and/or a glass fiber (e.g., a glass cloth or a glass fabric) are impregnated, for example, a photosensitive resin such as prepreg, AJINOMOTO BUILD-UP FILM® (ABF), FR-4, bismaleimide triazine (BT), or a photo-imageable dielectric (PID). Different layers of the forming the first insulation layer 120 may include the same insulating resin or different insulating resins.

In addition, in example embodiments, the first upper passivation film 125 and the first lower passivation film 124 may be a protective layer. For example, the first upper passivation film 125 and the first lower passivation film 124 may protect the lower substrate 100 from physical and chemical damage. The first upper passivation film 125 and the first lower passivation film 124 may correspond to a solder resist layer including a photo solder resist (PSR).

In example embodiments, the first wiring structure 110 may be electrically connected to each of the first lower pad 111 and the first upper pad 112. The first wiring structure 110 may include a ground (GND) pattern, a power (PWR) pattern, and a signal(S) pattern. For example, the first wiring structure 110 may include a metallic material including copper (Cu), aluminum (Al), silver (Ag), tin (Sn), gold (Au), nickel (Ni), lead (Pb), or titanium (Ti), or an alloy thereof.

In example embodiments, the first lower pad 111 may be formed on a lower surface of the first insulation layer 120. The first lower pad 111 may be electrically connected to the first wiring structure 110. The first lower passivation film 124 may cover a lower surface of the first lower insulation layer 122. The first lower passivation film 124 may expose portions of the first lower insulation layer 122. The first lower pad 111 may be formed on an exposed portion of the first lower insulation layer 122.

The semiconductor package P1 according to example embodiments may further include an external connection bump 130. The external connection bump 130 may be configured to electrically connect the lower substrate 100 to an external device. The external connection bump 130 may be attached to the first lower pad 111. The external connection bump 130 may have a spherical shape or an elliptically spherical shape, but a shape of the external connection bump 130 is not limited thereto. The external connection bump 130 may include tin (Sn), indium (In), bismuth (Bi), antimony (Sb), copper (Cu), silver (Ag), zinc (Zn), or lead (Pb), or a combination thereof. However, a material of the external connection bump 130 is not limited thereto.

In example embodiments, the first upper pad 112 may be formed on an upper surface of the first insulation layer 120. The first upper passivation film 125 may cover an upper surface of the first upper insulation layer 123. The first upper passivation film 125 may expose portions of the first upper insulation layer 123. The first upper pad 112 may be formed on exposed portion of the first upper insulation layer 123. The first upper pad 112 may be electrically connected with a lower semiconductor chip BC or a connector 40.

In example embodiments, a plurality of lower semiconductor chips BC may be disposed on the lower substrate 100. For example, referring to FIG. 3, a first lower semiconductor chip 10 and a second lower semiconductor chip 20 may be disposed on the lower substrate 100. For example, the first lower semiconductor chip 10 and the second lower semiconductor chip 20 may be disposed adjacent to each other on the lower substrate 100. For example, the first lower semiconductor chip 10 and the second lower semiconductor chip 20 may be disposed spaced apart from each other on the lower substrate 100. In the following description, the first direction D1 may be a width direction of the semiconductor package P1 and be a direction parallel to the surface of the lower substrate 100.

In example embodiments, the first lower semiconductor chip 10 and the second lower semiconductor chip 20 may be an integrated circuit (IC) in which multiple semiconductor components are integrated. The first lower semiconductor chip 10 and the second lower semiconductor chip 20 may be variously implemented. For example, at least one of the first lower semiconductor chip 10 or the second lower semiconductor chip 20 may be an application processor (AP) such as a central processing unit (CPU), a graphic processing unit (GPU), a field-programmable gate array (FPGA), a digital signal processor, a cryptographic processor, a microprocessor, or a microcontroller. However, the first lower semiconductor chip 10 and the second lower semiconductor chip 20 are not limited thereto. For example, at least one of the first lower semiconductor chip 10 or the second lower semiconductor chip 20 may be a logic chip such as an analog-digital converter (ADC) or an application-specific IC (ASIC). In another example, at least one of the first lower semiconductor chip 10 or the second lower semiconductor chip 20 may be a memory chip such as a volatile memory (e.g., a dynamic random access memory (DRAM)) or a non-volatile memory (e.g., a read-only memory (ROM) or a flash memory). The first lower semiconductor chip 10 and the second lower semiconductor chip 20 may include a combination of the above-described various chips, devices, or components.

In example embodiments, two or more of the plurality of lower semiconductor chips BC may be semiconductor chips of different types. For example, the first lower semiconductor chip 10 and the second lower semiconductor chip which are illustrated in FIG. 2, FIG. 3, and FIG. 4 may be semiconductor chips of different types. However, the first lower semiconductor chip 10 and the second lower semiconductor chip 20 may be semiconductor chips of an identical type.

In example embodiments, at least one of the plurality of lower semiconductor chips BC may be electrically connected to the lower substrate 100 through a plurality of conductive bumps 11. For example, in FIG. 3, the first lower semiconductor chip 10 may be electrically connected to the lower substrate 100 through a plurality of conductive bumps 11. Each of the conductive bumps 11 may be bonded onto and electrically connected to the first upper pads 112 of the lower substrate 100.

In example embodiments, at least one of the plurality of lower semiconductor chips BC may be electrically connected to the lower substrate 100 by a bonding wire 21. For example, in FIG. 3, the second lower semiconductor chip 20 may be electrically connected to the lower substrate 100 by a bonding wire 21.

In example embodiments, the plurality of lower semiconductor chips BC may be connected to the lower substrate 100 in different ways. For example, referring to FIG. 3, the first lower semiconductor chip 10 may be connected to the lower substrate 100 through the plurality of conductive bumps 11, and the second lower semiconductor chip 20 may be connected to the lower substrate 100 by the bonding wire 21.

In example embodiments, the semiconductor package P1 may have a multi-chip package in which the plurality of lower semiconductor chips BC may be disposed side by side on the lower substrate 100. For example, referring to FIG. 2 and FIG. 3, the first lower semiconductor chip 10 and the second lower semiconductor chip 20 may be disposed side by side in the first direction D1 parallel to the surface of the lower substrate 100. A plurality of semiconductor chips may be disposed side by side on the lower substrate 100 as such, and thus, the semiconductor package P1 of various types with an integrated structure may be formed.

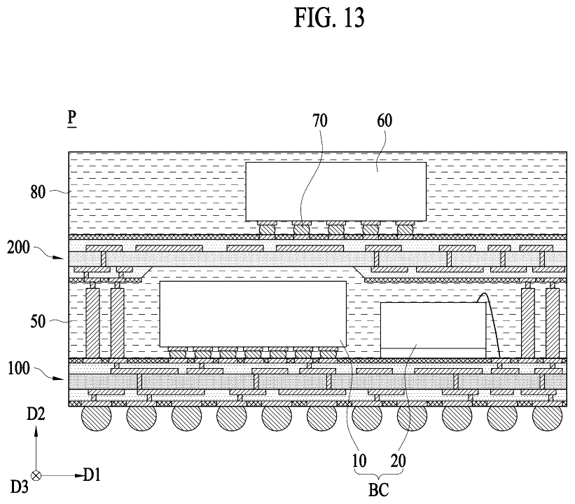

The semiconductor package P1 according to example embodiments may have an interposer package-on-package (IPOP) structure. In the IPOP structure, a plurality of semiconductor devices (e.g., a semiconductor chip or a semiconductor sub-package) may be stacked with the interposer substrate 200 disposed between chips or packages. For example, another semiconductor chip (e.g., an upper semiconductor chip 60 illustrated in FIG. 13) or another semiconductor package may be disposed above the interposer substrate 200 which is illustrated in FIG. 3.

In example embodiments, the interposer substrate 200 may be an organic interposer substrate having multiple organic insulation layers including an organic compound. Alternatively, the interposer substrate 200 may be a silicon substrate and may be a silicon interposer substrate including an insulation material such as a silicon oxide film or a silicon nitride film.

In example embodiments, the interposer substrate 200 may be disposed above the first lower semiconductor chip 10 and the second lower semiconductor chip 20. For example, the interposer substrate 200 may be disposed spaced apart in a second direction D2 perpendicular to an upper surface of the lower substrate 100, and the plurality of lower semiconductor chips BC may be disposed between the interposer substrate 200 and the lower substrate 100. In the following description, the second direction D2 may be a direction perpendicular to a plane formed by the first direction D1 and a third direction D3 crossing the first direction D1 and parallel to the upper surface of the lower substrate 100. The second direction D2 may be a direction perpendicular to the upper surface of the lower substrate 100 and a height direction of the semiconductor package P1.

In example embodiments, the interposer substrate 200 may include a first lower part surface 230 and an upper part surface 240 disposed on opposite sides of the interposer substrate 200. For example, the first lower part surface 230 of the interposer substrate 200 may face the lower substrate 100. The upper part surface 240 may be formed at a side opposite to the first lower part surface 230.

In example embodiments, the interposer substrate 200 may include a second insulation layer 220, a second wiring structure 210, a second lower pad 211, and a second upper pad 212. Each of the second wiring structure 210, the second lower pad 211, and the second upper pad 212 may be disposed in the second insulation layer 220.

In example embodiments, the second insulation layer 220 and the second wiring structure 210 in the second insulation layer 220 may form a wiring pattern for electrically connecting the second lower pad 211 and the second upper pad 212. For example, the second wiring structure 210 may include a metallic material including copper (Cu), aluminum (Al), silver (Ag), tin (Sn), gold (Au), nickel (Ni), lead (Pb), or titanium (Ti), or an alloy thereof.

In example embodiments, the second insulation layer 220 may include one or more layers. For example, the second insulation layer 220 may have a structure in which a second lower insulation layer 222 and a second lower passivation film 224 are stacked on a lower surface of a second core layer 221, and in which a second upper insulation layer 223 and a second upper passivation film 225 are stacked on an upper surface of the second core layer 221.

In example embodiments, each layer forming the second insulation layer 220 may include an insulating resin. The insulating resin may include a thermoset resin such as an epoxy resin, a thermoplastic resin such as polyimide, or such resins in which an inorganic filler and/or a glass fiber (e.g., a glass cloth or a glass fabric) are impregnated, for example, a photosensitive resin such as prepreg, ABF, FR-4, BT, or a PID. Different layers of the forming the second insulation layer 220 may include the same insulating resin or different insulating resins.

In addition, in example embodiments, the second upper passivation film 225 and the second lower passivation film 224 may be a protective layer. For example, the second upper passivation film 225 and the second lower passivation film 224 may protect the lower substrate 100 from physical and chemical damage and correspond to a solder resist layer including a PSR.

In example embodiments, the second lower pad 211 may be formed on a lower surface of the second insulation layer 220. The second lower pad 211 may be electrically connected with the second wiring structure 210. The second lower passivation film 224 may cover at least a portion of a lower surface of the second lower insulation layer 222. The second lower passivation film 224 may expose portions of the second lower insulation layer 222. The second lower pad 211 may be formed on an exposed portion of the second lower insulation layer 222.

In example embodiments, the semiconductor package PI may further include the plurality of connectors 40. The plurality of connectors 40 may be configured to electrically connect the lower substrate 100 and the interposer substrate 200.

In example embodiments, the connector 40 may be interposed between the lower substrate 100 and the interposer substrate 200. The connector 40 may be in contact with the upper surface of the lower substrate 100 and a lower surface of the interposer substrate 200. The connector 40 may electrically connect the lower substrate 100 and the interposer substrate 200. For example, the connector 40 may be in contact with the first upper pad 112 of the lower substrate 100 and the second lower pad 211 of the interposer substrate 200. Accordingly, the connector 40 may electrically connect the first wiring structure 110 and the second wiring structure 210.

In example embodiments, the connector 40 may have a bump shape, a pillar shape, or the like. The connector 40 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), or tin (Sn). However, the connector 40 may be formed from various conductive materials in addition thereto.

In example embodiments, the semiconductor package PI may have a multi-chip structure. In this case, the plurality of lower semiconductor chips BC may be disposed side by side along the surface of the lower substrate 100. For example, referring to a layout drawing illustrated in FIG. 2, the first lower semiconductor chip 10 and the second lower semiconductor chip 20 of the semiconductor package P1 may be disposed side by side in the first direction D1 in an area inside the plurality of connectors 40 disposed along an edge of the lower substrate 100.

In example embodiments, a molding layer 50 may be disposed between the lower substrate 100 and the interposer substrate 200. The molding layer 50 may fill an area between the lower substrate 100 and the interposer substrate 200. Accordingly, the molding layer 50 may cover and protect the lower substrate 100, the first lower semiconductor chip 10, the second lower semiconductor chip 20, the connector 40, or the like from an external environment. The molding layer 50 may include an epoxy molding compound (EMC) or a molding material such as an epoxy resin, an ultraviolet (UV) resin, a polyurethane resin, a silicone resin, or a silica filler. However, a molding material forming the molding layer 50 is not limited to the above-described materials.

In example embodiments, the molding layer 50 of the semiconductor package PI may be formed through a molding process. The molding process may be a process of filling a gap between the lower substrate 100 and the interposer substrate 200 with the molding material. For example, in the molding process, the molding material may be injected and cured between the lower substrate 100 and the interposer substrate 200 to form the molding layer 50.

In example embodiments, in the molding process, the molding material may gradually enter between the lower substrate 100 and the interposer substrate 200. The molding material may fill a space between the interposer substrate 200 and the lower substrate 100 while flowing along upper surfaces of the plurality of lower semiconductor chips BC. The molding material may form the molding layer 50 by filling the gap between the interposer substrate 200 and the lower substrate 100 and being solidified thereafter. The molding layer 50 formed as such may cover the upper surfaces of the plurality of lower semiconductor chips BC and fill all gaps between the plurality of lower semiconductor chips BC and the interposer substrate 200.

In example embodiments, two of the plurality of lower semiconductor chips BC which is mounted to the semiconductor package P1 may have different heights. For example, referring to FIG. 3, an upper surface of a first chip may have a height higher than that of a second chip disposed side by side on the lower substrate 100 with the first chip. In the following description, between the first lower semiconductor chip 10 and the second lower semiconductor chip 20 disposed side by side on the lower substrate 100, a height of an upper surface of the first lower semiconductor chip 10 may be relatively high and a height of an upper surface of the second lower semiconductor chip 20 may be relatively low. Also, in the following description, a height may be a distance or an interval in the second direction D2 perpendicular to the upper surface of the lower substrate 100 unless described otherwise.

In example embodiments, a height difference between the upper surfaces of the plurality of lower semiconductor chips BC may occur due to a thickness difference between the plurality of lower semiconductor chips BC. Here, a thickness may be a length in the second direction D2. For example, a thickness CT1 of the first lower semiconductor chip 10 may be thicker than a thickness CT2 of the second lower semiconductor chip 20. Accordingly, a height of an upper surface 12 of the first lower semiconductor chip 10 may be higher than a height of an upper surface 22 of the second lower semiconductor chip 20.

Alternatively, in example embodiments, the height difference between the upper surfaces of the plurality of lower semiconductor chips BC may occur due to a difference between connection structures of the plurality of lower semiconductor chips BC. For example, when the first lower semiconductor chip 10 is connected to the lower substrate 100 through the plurality of conductive bumps 11, and when the second lower semiconductor chip 20 is connected to the lower substrate 100 by the bonding wire 21, the height of the upper surface 12 of the first lower semiconductor chip 10 may be higher than the height of the upper surface 22 of the second lower semiconductor chip 20 because of a height of the plurality of conductive bumps 11.

In example embodiments, in order to evenly spread the molding material between the lower substrate 100 and the interposer substrate 200 during the molding process, the semiconductor package P1 may be formed so that intervals between the interposer substrate 200 and the plurality of lower semiconductor chips BC which has the upper surfaces of different heights are formed at an appropriate level.

When a difference between the intervals between the plurality of lower semiconductor chips BC and the interposer substrate 200 is large, a flow of the molding material may be stagnant on an upper surface of a lower semiconductor chip having a relatively narrow interval, and the flow of the molding material may be smooth on an upper surface of a lower semiconductor chip having a relatively wide interval. Thus, an imbalance in the flow of the molding material may be caused. In example embodiments, areas respectively corresponding to the plurality of lower semiconductor chips BC in the first lower part surface 230 of the interposer substrate 200 may be formed to have different heights so that the difference between the intervals between the interposer substrate 200 and the plurality of lower semiconductor chips BC which has the upper surfaces of the different heights is decreased and an imbalance in the flow of the molding material may be inhibited or prevented.

For example, referring to FIGS. 3 and 4, the first lower part surface 230 of the interposer substrate 200 may include a first lower part surface 230a and a second lower part surface 230b.

The first lower part surface 230a may be a part corresponding to a position of the first lower semiconductor chip 10 in an area overlapping the first lower semiconductor chip 10 in the second direction D2 perpendicular to the surface of the lower substrate 100. The second lower part surface 230b may be a part corresponding to a position of the second lower semiconductor chip 20 in an area overlapping the second lower semiconductor chip 20 in the second direction D2 perpendicular to the surface of the lower substrate 100. Here, a height of the first lower part surface 230a may be higher than a height of the second lower part surface 230b. In other words, when an interval from the upper surface of the lower substrate 100 to the first lower part surface 230a of the interposer substrate 200 is referred to as a first interval IH1, and when an interval from the upper surface of the lower substrate 100 to the second lower part surface 230b of the interposer substrate 200 is referred to as a second interval IH2, the second interval IH2 may be smaller than the first interval IH1. Accordingly, respective intervals between the interposer substrate 200 and each of the first lower semiconductor chip 10 and the second lower semiconductor chip 20 which have upper surfaces of different heights may be formed to be equal or similar to each other. When respective intervals between the interposer substrate 200 and each of the first lower semiconductor chip 10 and the second lower semiconductor chip 20 have upper surfaces of different heights, a molding material flow on an upper surface of each of the lower semiconductor chips may be inhibited or prevented from forming in an imbalanced manner.

In illustrations of FIG. 3 and FIG. 4, the height of the second lower part surface 230b of the interposer substrate 200 may be approximately equal to a height of another part (hereinafter referred to as a remaining lower part surface) not corresponding to the first lower semiconductor chip 10 and the second lower semiconductor chip 20 in the first lower part surface 230 of the interposer substrate 200. However, in contrast, the height of the second lower part surface 230b of the interposer substrate 200 may be relatively higher or lower than the height of the remaining lower part surface.

In example embodiments, the first lower part surface 230a of the interposer substrate 200 may correspond to a floor surface of a recess structure recessed toward the second core layer 221 further than the second lower part surface 230b. For example, referring to FIGS. 3 and 4, the part, in the first lower part surface 230 of the interposer substrate 200, corresponding to the position of the first lower semiconductor chip 10 may have a recess structure recessed toward the second core later 221. A part corresponding to a floor of the recess structure may correspond to the first lower part surface 230a. A first stepped part 231 corresponding to a side wall of the recess structure may be formed between the first lower part surface 230a and the second lower part surface 230b.

In example embodiments, the recess structure of the first lower part surface 230 of the interposer substrate 200 may be formed by performing an etching process on a portion of the first lower part surface 230 which is flat. Various etching method such as a wet etching process, a dry etching process, or a plasma etching process may be performed in combination in the etching process. For example, when the second insulation layer 220 of the interposer substrate 200 is etched, the wet etching process may be applied. When the second wiring structure 210 of the interposer substrate 200 is etched, a laser drilling process may be applied. Through such various etching methods, the recess structure of the first lower part surface 230 of the interposer substrate 200 may be formed by etching at least a portion of the second core layer 221 and the second upper insulation layer 223 which is positioned thereon as well as the second lower passivation film 224 or the second lower insulation layer 222 of the interposer substrate 200.

In example embodiments, when a plurality of insulation layers are etched to form the recess structure, the first stepped part 231 of the interposer substrate 200 may be formed in a shape in which a cross section of two or more stacked insulation layers (e.g., the second lower passivation film 224 and the second lower insulation layer 222) is exposed.

In example embodiments, at least a portion of the first lower semiconductor chip 10 may be positioned in the recess structure of the interposer substrate 200. For example, referring to FIG. 4, the upper surface 12 of the first lower semiconductor chip 10 and parts adjacent thereto may be disposed in the recess structure and disposed at a position overlapping the first stepped part 231 of the interposer substrate 200 in the first direction D1. However, a position of the upper surface 12 of the first lower semiconductor chip 10 is not limited thereto. For example, the height of the upper surface 12 of the first lower semiconductor chip 10 may be formed to be lower than or equal to the height of the second lower part surface 230b of the interposer substrate 200. In this case, the first lower semiconductor chip 10 may not overlap the first stepped part 231 of the interposer substrate 200 in the first direction D1.

As such, as the recess structure is formed on the first lower part surface 230 of the interposer substrate 200, a sufficient gap illustrated by reference numeral ID1 in which the molding material may smoothly flow may be formed between the first lower semiconductor chip 10 and the interposer substrate 200. In addition, since the thickness CT1 of the first lower semiconductor chip 10 may be further increased to correspond to the recess structure, heat dissipation performance may be also improved.

In example embodiments, thicknesses IT1 and IT2 of parts corresponding to the first lower part surface 230a and the second lower part surface 230b in the interposer substrate 200 may be formed to be different from each other to implement the above-described recess structure. For example, referring to FIG. 4, a thickness IT1 between the upper part surface 240 and the first lower part surface 230a of the interposer substrate 200 may be thinner than a thickness IT2 between the upper part surface 240 and the second lower part surface 230b of the interposer substrate 200.

Also, in example embodiments, a difference between the height of the upper surface 12 of the first lower semiconductor chip 10 and the height of the first lower part surface 230a may be allowed to be greater than a difference between the height of the upper surface 12 of the first lower semiconductor chip 10 and the height of the second lower part surface 230b of the interposer substrate 200. When the difference between the height of the upper surface 12 of the first lower semiconductor chip 10 and the height of the first lower part surface 230a is allowed to be greater than the difference between the height of the upper surface 12 of the first lower semiconductor chip 10 and the height of the second lower part surface 230b of the interposer substrate 200, respective intervals ID1 and ID2 between the interposer substrate 200 and each of the first lower semiconductor chip 10 and the second lower semiconductor chip 20 may be equal or similar to each other.

In example embodiments, a height difference between the first lower part surface 230a and the second lower part surface 230b of the interposer substrate 200 (hereinafter referred to as a cavity height) may correspond to a height difference between the upper surface 12 of the first lower semiconductor chip 10 and the upper surface 22 of the second lower semiconductor chip 20 (hereinafter referred to as a chip height difference). For example, the cavity height may be substantially equal to the chip height difference. However, the cavity height may be greater or less than the chip height difference at a level at which the imbalance in the flow of the molding material may be reduced or eliminated.

Alternatively, the height difference between the first lower part surface 230a and the second lower part surface 230b of the interposer substrate 200 may correspond to a thickness difference between the first lower semiconductor chip 10 and the second lower semiconductor chip 20.

As such, the recess structure of the interposer substrate 200 and the first lower semiconductor chip 10 which has a height of an upper surface higher than that of the second lower semiconductor chip 20 may be disposed to face each other. When the recess structure of the interposer substrate 200 and the first lower semiconductor chip 10 having a height of the upper surface higher than that of the second lower semiconductor chip 20 are disposed to face each other, a thicker semiconductor chip may be mounted by sufficiently securing an interval ID1 between the upper surface 12 of the first lower semiconductor chip 10 and the interposer substrate 200, and heat dissipation efficiency of a semiconductor chip may be also increased. Furthermore, the imbalance in the flow of the molding material may be inhibited to prevented in the molding process by allowing the interval ID1 between the upper surface 12 of the first lower semiconductor chip 10 and the interposer substrate 200 to be formed to be equal or similar to an interval ID2 between the upper surface 22 of the second lower semiconductor chip 20. Accordingly, a void may not be formed on an upper surface of a lower semiconductor chip. Also, a yield of the semiconductor package P1 may be increased, and uniformity of quality may be improved.

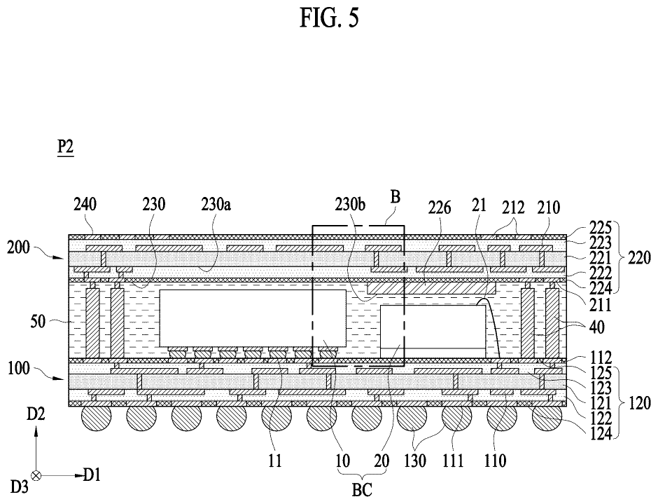

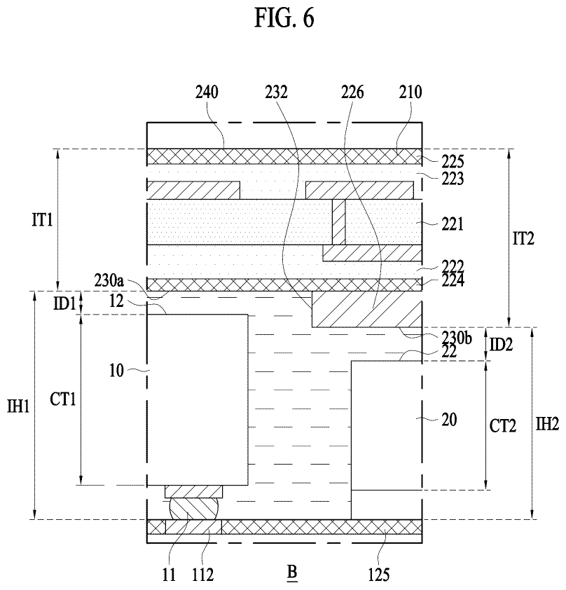

In a semiconductor package P2 according to other example embodiments of the present disclosure, the interposer substrate 200 may further include an additional insulation layer in a portion of areas of the first lower part surface 230. When the interposer substrate 200 includes an additional insulation layer in a portion of areas of the first lower part surface 230, respective intervals between the interposer substrate 200 and each of the first lower semiconductor chip 10 and the second lower semiconductor chip 20 may be formed to be equal or similar to each other. Hereinafter, the semiconductor package P2 according to other example embodiments will be described with reference to FIG. 5 and FIG. 6.

FIG. 5 is an exemplary cross-sectional diagram illustrating a semiconductor package according to another example embodiment.

FIG. 6 is an exploded diagram illustrating part B of FIG. 5.

In the semiconductor package P2 described in FIG. 5 and FIG. 6, since all other technical features excluding structures of the first lower part surface 230a and the second lower part surface 230b of the interposer substrate 200 are identical to technical features of the semiconductor package P1 described with reference to FIG. 2, FIG. 3, and FIG. 4, redundant descriptions similar to those of FIG. 2, FIG. 3, and FIG. 4 may be omitted or simplified.

Referring to FIG. 5 and FIG. 6, the first lower part surface 230 of the interposer substrate 200 may include the first lower part surface 230a and the second lower part surface 230b. The first lower part surface 230a may overlap in the second direction D2 with a position of the first lower semiconductor chip 10. The second lower part surface 230b may overlap in the second direction D2 with the second lower semiconductor chip 20. For example, the first lower part surface 230 of the interposer substrate 200 may include the first lower part surface 230a corresponding to the position of the first lower semiconductor chip 10, and the second lower part surface 230b corresponding to the second lower semiconductor chip 20.

In other example embodiments, the interposer substrate 200 may further include a first protrusion part 226 protruding from a position on the first lower part surface 230 overlapping in the second direction D2 with the second lower semiconductor chip 20 toward the lower substrate 100. In this case, a lower surface of the first protrusion part 226 may form the second lower part surface 230b.

In an example embodiment, the first protrusion part 226 may have an area in the plane formed by the first direction D1 and the third direction D3 greater than or equal to an area of the second lower semiconductor chip 20. For example, the first protrusion part 226 may have an area about equal to the area of the second lower semiconductor chip 20. For example, the first protrusion part 226 may have an area within about 0 to 20 percent, or about 0 to 10 percent of the area of the second lower semiconductor chip 20.

In other example embodiments, the first protrusion part 226 of the interposer substrate 200 may be formed from a material identical to that of at least one part of the second insulation layer 220. For example, the first protrusion part 226 of the interposer substrate 200 may be formed by further stacking one insulation layer of a material identical to that of the second lower passivation film 224 at the position overlapping with the second lower semiconductor chip 20 in the second direction D2.

As such, as an additional insulation layer (namely, the first protrusion part 226) may overlap the second lower semiconductor chip 20 in the second direction D2, a height illustrated by reference numeral IH1 of the first lower part surface 230a of the interposer substrate 200 may be higher than a height illustrated by reference numeral IH2 of the second lower part surface 230b of the interposer substrate 200. That is, the interval IH1 from an upper surface of the lower substrate 100 to the first lower part surface 230a of the interposer substrate 200 may be larger than the interval IH2 from the upper surface of the lower substrate 100 to the second lower part surface 230b of the interposer substrate 200. Accordingly, since the respective intervals ID1 and ID2 between the interposer substrate 200 and each of the first lower semiconductor chip 10 and the second lower semiconductor chip 20, which have upper surfaces of different heights, may be formed to be equal or similar to each other, a molding material flow on the respective upper surfaces of the first and second lower semiconductor chips 10 and 20 may be inhibited or prevented from occurring in an imbalanced manner.

In example embodiments illustrated in FIG. 5 and FIG. 6, the height of the first lower part surface 230a of the interposer substrate 200 may be approximately equal to a height of another part (hereinafter referred to as a remaining lower part surface) not corresponding to the first lower semiconductor chip 10 and the second lower semiconductor chip 20 in the first lower part surface 230 of the interposer substrate 200. However, in an example embodiment, the height of the second lower part surface 230b of the interposer substrate 200 may be relatively higher or lower than the height of the remaining lower part surface.

In other example embodiments, the first protrusion part 226 may protrude to have a thickness (here, the thickness may be a distance in the second direction D2) sufficient for reducing a difference between the respective intervals ID1 and ID2 between the interposer substrate 200 and each of the first lower semiconductor chip 10 and the second lower semiconductor chip 20. In this case, the first protrusion part 226 may have a thickness for facing at least a portion of the first lower semiconductor chip 10 in the first direction D1. For example, referring to FIG. 6, as the first protrusion part 226 may be formed on the interposer substrate 200, a second stepped part 232 may be formed at an edge of the first protrusion part 226, and the upper surface 12 of the first lower semiconductor chip 10 and parts adjacent thereto may be disposed at a position overlapping the second stepped part 232 or the first protrusion part 226 of the interposer substrate 200 in the first direction D1.

However, a thickness of the first protrusion part 226 is not limited thereto. For example, a lower surface of the first protrusion part 226, namely, the height of the second lower part surface 230b may be formed to be higher than or equal to a height of the upper surface 12 of the first lower semiconductor chip 10. In this case, the first lower semiconductor chip 10 may not overlap the first protrusion part 226 or the second stepped part 232 of the interposer substrate 200 in the first direction D1.

In other example embodiments, as the first protrusion part 226 may be formed on the interposer substrate 200, thicknesses corresponding to the first lower part surface 230a and the second lower part surface 230b in the interposer substrate 200 may be different from each other. For example, referring to FIG. 6, the thickness IT1 between the upper part surface 240 and the first lower part surface 230a of the interposer substrate 200 may be thinner than the thickness IT2 between the upper part surface 240 and the second lower part surface 230b of the interposer substrate 200.

Also, in other example embodiments, the first protrusion part 226 may be formed on the interposer substrate 200, and a difference between the height of the upper surface 12 of the first lower semiconductor chip 10 and the height of the first lower part surface 230a of the interposer substrate 200 may be greater than a difference between the height of the upper surface 12 of the first lower semiconductor chip 10 and the height of the second lower part surface 230b of the interposer substrate 200. Accordingly, the respective intervals ID1 and ID2 between the interposer substrate 200 and each of the first lower semiconductor chip 10 and the second lower semiconductor chip 20 may be formed to be equal or similar to each other.

In other example embodiments, a height difference between the first lower part surface 230a and the second lower part surface 230b of the interposer substrate 200 (hereinafter referred to as the thickness of the first protrusion part 226) may correspond to a height difference between the upper surface 12 of the first lower semiconductor chip 10 and the upper surface 22 of the second lower semiconductor chip 20 (hereinafter referred to as a chip height difference). For example, the thickness of the first protrusion part 226 may be substantially equal to the chip height difference. However, the thickness of the first protrusion part 226 may be greater or less than the chip height difference. For example, even when the thickness of the first protrusion part 226 is within about 0 to 50 percent (%), or about 0 to 25%, or about 0 to 10% of the chip height difference, an imbalance in a flow of a molding material may be reduced.

Alternatively, in other example embodiments, the height difference between the first lower part surface 230a and the second lower part surface 230b of the interposer substrate 200 may correspond to a thickness difference between the first lower semiconductor chip 10 and the second lower semiconductor chip 20.

As such, the first protrusion part 226 of the interposer substrate 200 may be disposed above the second lower semiconductor chip 20 which has a height of an upper surface lower than that of the first lower semiconductor chip 10. When the first protrusion part 226 of the interposer substrate 200 is disposed above the second lower semiconductor chip 20 which has a height of an upper surface lower than that of the first lower semiconductor chip 10, the interval ID1 between the upper surface 12 of the first lower semiconductor chip 10 and the interposer substrate 200 may be formed to be equal or similar to the interval ID2 between the upper surface 22 of the second lower semiconductor chip 20 and the interposer substrate 200, and an imbalance in the flow of the molding material may be inhibited or prevented in a molding process. Accordingly, a void may not be formed on an upper surface of a lower semiconductor chip when an imbalance in the flow of the molding material may be inhibited or prevented from occurring. Also, a yield of the semiconductor package P2 may be increased, and uniformity of quality may be improved.

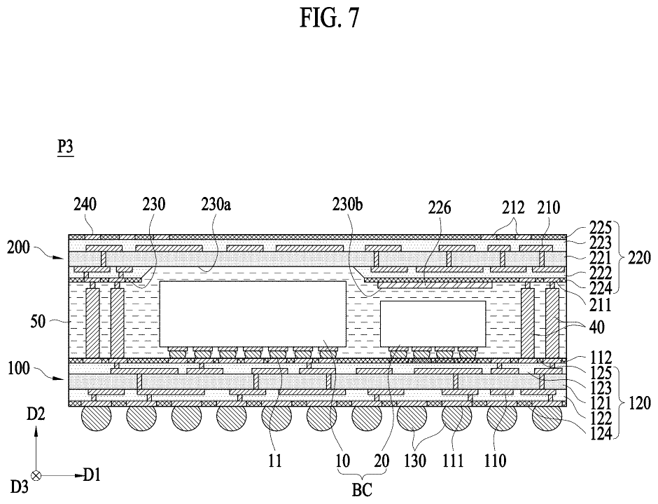

Referring to FIG. 6 and FIG. 7, in other example embodiments, when a height difference between the upper surface 12 of the first lower semiconductor chip 10 and the upper surface 22 of the second lower semiconductor chip 20 is large, a recess area may be formed between the first lower part surface 230 and the interposer substrate 200, and an additional insulation layer may be provided in the recess area. For example, the second lower insulation layer 222 may be the additional insulation layer formed in a recess area between the first lower part surface 230 and the interposer substrate 200. When a height difference between the upper surface 12 of the first lower semiconductor chip 10 and the upper surface 22 of the second lower semiconductor chip 20 is large, and a recess are may be formed between the first lower part surface 230 and the interposer substrate 200, and an additional insulation layer may be provided in the recess area, respective intervals between the interposer substrate 200 and each of the first lower semiconductor chip 10 and the second lower semiconductor chip 20 may be formed to be equal or similar to each other.

FIG. 7 is an exemplary cross-sectional diagram illustrating a semiconductor package P3 according to another example embodiment.

Referring to FIG. 7, the first lower part surface 230a of the first lower part surface 230 of the interposer substrate 200 may be formed by partially etching the second insulation layer 220. The second lower part surface 230b may be formed by stacking an additional insulation layer (namely, the first protrusion part 226) on the second lower passivation film 224.

A description for a structure of the first lower part surface 230a of the interposer substrate 200 which is described with reference to FIG. 2, FIG. 3, and FIG. 4 may be referenced for a structure of the first lower part surface 230a of the interposer substrate 200 in the semiconductor package P3 described in FIG. 7. In addition, a description for a structure of the second lower part surface 230b of the interposer substrate 200 which is described with reference to FIG. 5 and FIG. 6 may be referenced for a structure of the second lower part surface 230b of the interposer substrate 200 in the semiconductor package P3 described with reference to FIG. 7.

Meanwhile, in the semiconductor package P3 illustrated in FIG. 7, the lower substrate 100 and the plurality of lower semiconductor chips BC which is disposed thereon may be described in detail with reference to the above description for FIG. 2, FIG. 3, and FIG. 4.

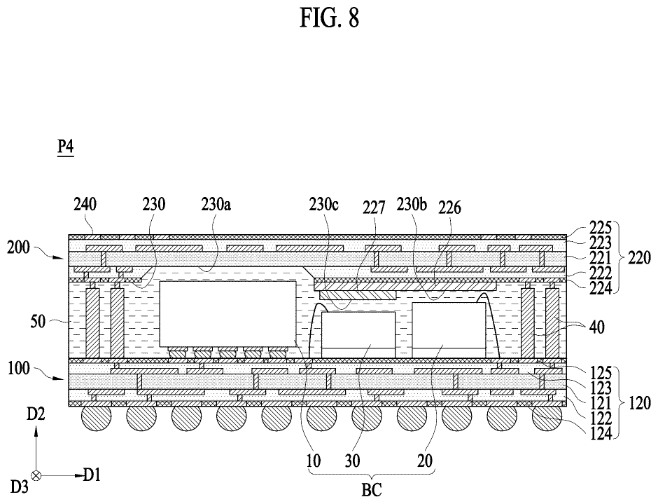

Referring to FIG. 8, in other example embodiments, the semiconductor package P4 may further include a third lower semiconductor chip 30 of which a height of an upper surface is lower than those of the first lower semiconductor chip 10 and the second lower semiconductor chip 20. Correspondingly, the interposer substrate 200 may further include a third lower part surface 230c of which a height may be lower than heights of the first lower part surface 230a and the second lower part surface 230b.

FIG. 8 is an exemplary cross-sectional diagram illustrating a semiconductor package P4 according to another example embodiment.

A description for a structure of the first lower part surface 230a of the interposer substrate 200 which is described with reference to FIG. 2, FIG. 3, and FIG. 4 may be referenced for a structure of the first lower part surface 230a of the interposer substrate 200 in the semiconductor package P4 described in FIG. 8. In addition, a description of a structure of the second lower part surface 230b of the interposer substrate 200, which is described with reference to FIG. 5 and FIG. 6, may be referenced for understanding a structure of the second lower part surface 230b of the interposer substrate 200 in the semiconductor package P4 described in FIG. 8.

In other example embodiments, the semiconductor package P4 may have a multi-chip structure mounted with three or more lower semiconductor chips BC. For example, referring to FIG. 8, the first lower semiconductor chip 10, the second lower semiconductor chip 20, and the third lower semiconductor chip 30, which may have different upper surface heights, may be disposed side by side on the lower substrate 100 between the plurality of connectors 40.

In other example embodiments, a height of an upper surface of the third lower semiconductor chip 30 may be lower than heights of upper surfaces of the first lower semiconductor chip 10 and the second lower semiconductor chip 20. Given such a height difference, the third lower part surface 230c, which has a height lower than that of the second lower part surface 230b, may be disposed at a position on the first lower part surface 230 of the interposer substrate 200 overlapping the third lower semiconductor chip 30 in the second direction D2.

In other example embodiments, the third lower part surface 230c may be formed as an additional protrusion structure provided on a surface of the first protrusion part 226 which forms the second lower part surface 230b. For example, referring to FIG. 8, a first protrusion part 226 may be disposed on the first lower part surface 230 of the interposer substrate 200, and a second protrusion part 227 protruding toward the lower substrate 100 may be disposed at a position, on a surface of the first protrusion part 226, corresponding to the third lower semiconductor chip 30. For example, the second protrusion part 227 may overlap the third lower semiconductor chip 30 in the second direction D2. A lower surface of the second protrusion part 227 may form the third lower part surface 230c.

In an example embodiment, the second protrusion part 227 may have an area in the plane formed by the first direction D1 and the third direction D3 greater than or equal to an area of the third lower semiconductor chip 30. For example, the second protrusion part 227 may have an area about equal to the area of the third lower semiconductor chip 30. For example, the second protrusion part 227 may have an area within about 0 to 20 percent, or about 0 to 10 percent of the area of the third lower semiconductor chip 30.

In other example embodiments, each of the first protrusion part 226 and the second protrusion part 227 of the interposer substrate 200 may be formed from an insulation material. For example, in a production process for the interposer substrate 200, additional insulation layers formed from a material identical to that of the second lower passivation film 224 may be stacked on the second lower passivation film 224, the additional insulation layers may respectively form the first protrusion part 226 and the second protrusion part 227, and lower surfaces of the first protrusion part 226 and the second protrusion part 227 may respectively form the second lower part surface 230b and the third lower part surface 230c.

As such, to correspond to the plurality of semiconductor chips BC which has different upper surface heights, the first lower part surface 230 of the interposer substrate 200 may be formed to be divided into a plurality of areas (namely, the first lower part surface 230a, the second lower part surface 230b, and the third lower part surface 230c) having different heights. When the first lower part surface 230 of the interposer substrate 200 is formed to be divided into a plurality of areas having different heights, respective intervals between the interposer substrate 200 and each of the plurality of semiconductor chips BC may be formed to be equal or similar to each other. Accordingly, since an imbalance in a flow of a molding material may be inhibited or prevented in a molding process, a void may not be formed on upper surfaces of the plurality of lower semiconductor chips BC, a yield of the semiconductor package P4 may be increased, and uniformity of quality may be improved.

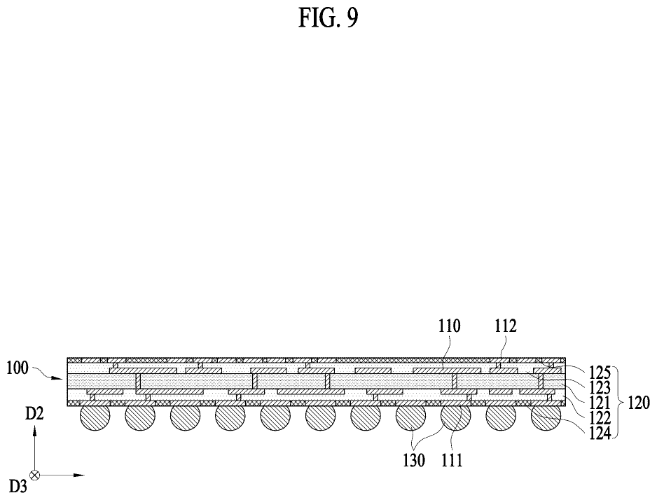

Hereinafter, a manufacturing process for a semiconductor package P according to example embodiments will be described with reference to FIGS. 9 to 13.

FIGS. 9 to 13 are cross-sectional diagrams illustrating a manufacturing process for a semiconductor package P according to an example embodiment.

The semiconductor package P which is described in FIGS. 9 to 13 may correspond to the semiconductor package P1 which is described with reference to FIG. 2, FIG. 3, and FIG. 4. Also, the manufacturing process described in FIGS. 9 to 13 may be identically applied to manufacturing of the semiconductor packages P2, P3, and P4 described with reference to FIGS. 5 to 8.

Referring to FIG. 9, the lower substrate 100 which includes the first wiring structure 110, the first insulation layer 120, and the external connection bump 130 may be formed. The first wiring structure 110 may be formed in the first insulation layer 120, which may have a plurality of layers. The first lower pad 111 and the first upper pad 112 may be exposed toward an outside of the first insulation layer 120 and each electrically connected to the first wiring structure 110.

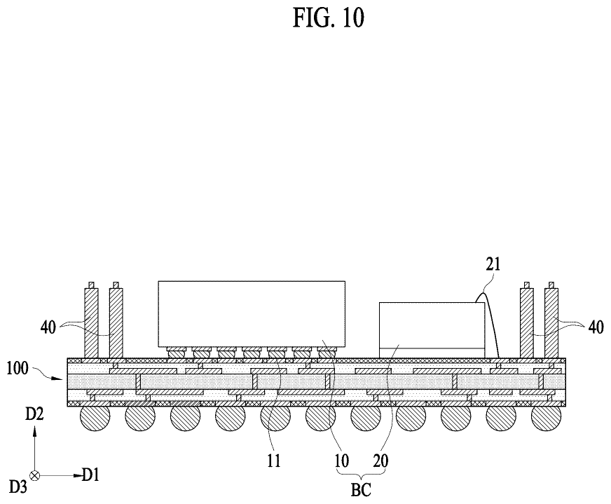

Referring to FIG. 10, the plurality of lower semiconductor chips BC, which may include the first lower semiconductor chip 10 and the second lower semiconductor chip 20, may be disposed on the lower substrate 100. The plurality of lower semiconductor chips BC may be disposed side by side in the first direction D1 to form a multi-chip structure. In this case, at least two of the plurality of lower semiconductor chips BC may have different upper surface heights.

In addition, in example embodiments, one or more connectors 40 may be disposed at sides of the plurality of lower semiconductor chips BC. For example, the plurality of lower semiconductor chips BC may be disposed between the connectors 40. The connector 40 may be electrically connected to the lower substrate 100.

In example embodiments, each of the connectors 40 may have a width in the plane formed by the first direction D1 and the third direction D3. For example, the width of the connectors 40 may be the same in the height direction. In another example, the connectors 40 may have a step in a sidewall, and the connectors 40 may have portions with different widths. In example embodiments, the connectors 40 may be formed of a single layer or may include multiple layers.

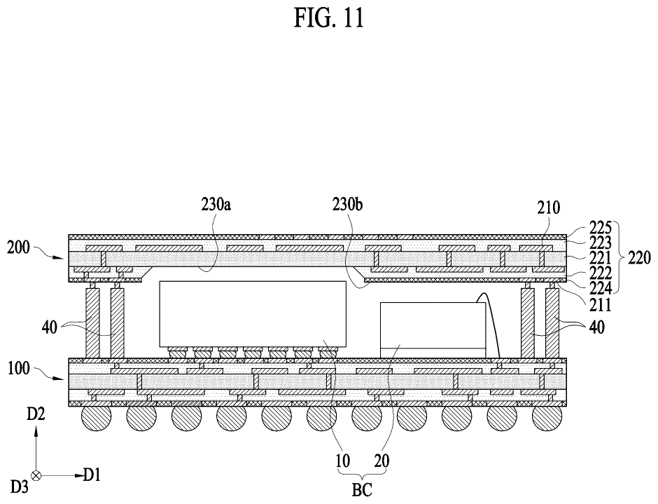

Referring to FIG. 11, the interposer substrate 200 may be disposed above the plurality of lower semiconductor chips BC. The first lower part surface 230a and the second lower part surface 230b of the interposer substrate 200, which have different heights, may correspond to the first lower semiconductor chip 10 and the second lower semiconductor chip 20, which have upper surfaces of different heights. Structures of the first lower part surface 230a and the second lower part surface 230b may be described in detail with reference to FIG. 2, FIG. 3, and FIG. 4.

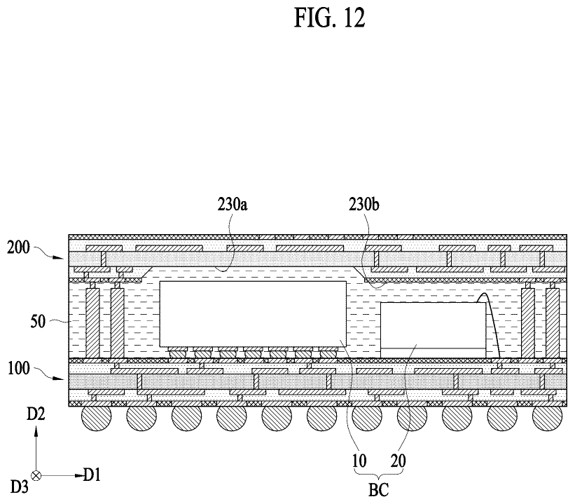

Referring to FIG. 12, the molding layer 50 may be formed by filling a gap between the interposer substrate 200 and the lower substrate 100 with a molding material.

In example embodiments, when the first lower part surface 230 of the interposer substrate 200 has the first lower part surface 230a and the second lower part surface 230b having the different heights, a difference between respective intervals between the interposer substrate 200 and each of the plurality of lower semiconductor chips BC may be formed within an appropriated range, despite a thickness difference between the plurality of lower semiconductor chips BC.

In other words, in a multi-chip structure in which the plurality of lower semiconductor chips BC may have different thicknesses, an imbalance in a flow of a molding material may be inhibited or prevented a molding process, wherein an interval (e.g., the reference numeral ID1 in FIG. 4) between a lower semiconductor chip and the interposer substrate 200 may not to be excessively narrower or larger than an interval (e.g. the reference numeral ID2 in FIG. 4) between another lower semiconductor chip and the interposer substrate 200. Accordingly, the molding material may evenly spread at a uniform speed throughout the upper surfaces of the plurality of lower semiconductor chips BC without excessively quickly or slowly flowing only on an upper surface of one semiconductor chip, and thus, a void may be inhibited or prevented from occurring in the molding layer 50.

Referring to FIG. 13, an upper semiconductor chip 60 and an upper molding layer 80 surrounding the upper semiconductor chip 60 may be disposed on the interposer substrate 200. For example, the upper semiconductor chip 60 may be a memory device including a high bandwidth memory (HBM) device or a DRAM. The upper semiconductor chip 60 may be electrically connected to the interposer substrate 200 through an upper connector 70. Alternatively, the upper semiconductor chip 60 may be electrically connected to the interposer substrate 200 through an upper substrate (not illustrated).

As such, the semiconductor package P according to example embodiments may have an IPOP structure in which an additional semiconductor chip may be disposed on the interposer substrate 200.

Example embodiments of the present disclosure have been described in detail above, but the scope of the present disclosure is not limited thereto. It will be apparent to those skilled in the art that various changes and modifications may be allowed within the scope of the technical spirit of the present disclosure. In addition, example embodiments may be implemented without one or more elements thereof, and example embodiments may be implemented in combination with another.

What is claimed is:

1. A semiconductor package comprising:
a lower substrate comprising a lower wiring structure;
a first lower semiconductor chip disposed on the lower substrate;
a second lower semiconductor chip disposed on the lower substrate adjacent to the first lower semiconductor chip in a first direction parallel to a surface of the lower substrate;
an interposer substrate disposed above the first lower semiconductor chip and the second lower semiconductor chip and comprising a lower part surface facing the lower substrate and an upper part surface that is a surface opposite to the lower part surface; and
a molding layer disposed between the lower substrate and the interposer substrate,
wherein the first lower semiconductor chip and the second lower semiconductor chip have different heights in a second direction perpendicular to the surface of the lower substrate, and
a thickness of the interposer substrate at a first position overlapping the first lower semiconductor chip is different than a thickness of the interposer substrate at a second position overlapping the second lower semiconductor chip.

2. The semiconductor package of claim 1, wherein the second lower semiconductor chip is disposed on the lower substrate spaced apart from the first lower semiconductor chip,
a height of an upper surface of the first lower semiconductor chip is higher than a height of an upper surface of the second lower semiconductor chip in the second direction,
the lower part surface of the interposer substrate comprises a first lower part surface corresponding to a position of the first lower semiconductor chip and a second lower part surface corresponding to a position of the second lower semiconductor chip, and
a thickness between the upper part surface and the first lower part surface of the interposer substrate is thinner than a thickness between the upper part surface and the second lower part surface of the interposer substrate.

3. The semiconductor package of claim 2, further comprising a recess, wherein the first lower part surface of the interposer substrate is a floor surface of the recess recessed further than the second lower part surface of the interposer substrate.

4. The semiconductor package of claim 3, wherein the interposer substrate further comprises a first stepped part disposed along an edge of the first lower part surface, and
at least a portion of the first lower semiconductor chip overlaps the first stepped part in the first direction.

5. The semiconductor package of claim 2, wherein the interposer substrate further comprises:
an insulation layer covering an upper part of the molding layer; and
a protrusion part protruding from a position, on a lower part surface of the insulation layer, overlapping the second lower semiconductor chip toward the lower substrate, and
a lower surface of the protrusion part forms the second lower part surface.

6. The semiconductor package of claim 5, wherein the interposer substrate further comprises a second stepped part disposed along an edge of the second lower part surface, and
at least a portion of the first lower semiconductor chip overlaps the second stepped part in the first direction.

7. The semiconductor package of claim 1, wherein an interval between the first lower semiconductor chip and the interposer substrate is equal to an interval between the second lower semiconductor chip and the interposer substrate.

8. The semiconductor package of claim 1, wherein an interval between an upper surface of the first lower semiconductor chip and a first lower part surface of the interposer substrate at the first position corresponds to a difference between the height of an upper surface of the first lower semiconductor chip and the height of an upper surface of the second lower semiconductor chip.

9. The semiconductor package of claim 1, wherein the molding layer covers the first lower semiconductor chip and the second lower semiconductor chip.

10. The semiconductor package of claim 1, further comprising a plurality of connectors configured to electrically connect the lower substrate and the interposer substrate,
wherein the first lower semiconductor chip and the second lower semiconductor chip are disposed side by side between at least two connectors of the plurality of connectors in a first direction.

11. The semiconductor package of claim 1, wherein a thickness of the first lower semiconductor chip is thicker than a thickness of the second lower semiconductor chip.

12. The semiconductor package of claim 11, wherein in the second direction, a difference between a height of a first lower part surface of the interposer substrate and a height of a second lower part surface of the interposer substrate corresponds to a difference between the thickness of the first lower semiconductor chip and the thickness of the second lower semiconductor chip.

13. The semiconductor package of claim 2, further comprising a third lower semiconductor chip disposed adjacent to the second lower semiconductor chip,
wherein a height of an upper surface of the third lower semiconductor chip is lower than the height of the upper surface of the second lower semiconductor chip in the second direction,
the lower part surface of the interposer substrate further comprises a third lower part surface overlapping the third lower semiconductor chip, and
the thickness between the upper part surface and the second lower part surface of the interposer substrate is thinner than a thickness between the upper part surface and the third lower part surface of the interposer substrate.

14. A semiconductor package comprising:
a lower substrate;
a first lower semiconductor chip disposed on the lower substrate;
a second lower semiconductor chip disposed adjacent to the first lower semiconductor chip on the lower substrate; and
an interposer substrate comprising a first lower part surface disposed above and spaced apart from the first lower semiconductor chip and a second lower part surface disposed above and spaced apart from the second lower semiconductor chip,
wherein a height of an upper surface of the first lower semiconductor chip is higher than a height of an upper surface of the second lower semiconductor chip, and
a height difference between the upper surface of the first lower semiconductor chip and the first lower part surface of the interposer substrate is greater than a height difference between the upper surface of the first lower semiconductor chip and the second lower part surface of the interposer substrate.

15. The semiconductor package of claim 14, wherein a difference between a height of the first lower part surface and a height of the second lower part surface of the interposer substrate corresponds to a difference between the height of the upper surface of the first lower semiconductor chip and the height of the upper surface of the second lower semiconductor chip.

16. The semiconductor package of claim 14, further comprising a molding layer disposed between the lower substrate and the interposer substrate,
wherein the molding layer is formed in a gap between the upper surface of the first lower semiconductor chip and the first lower part surface of the interposer substrate and between the upper surface of the second lower semiconductor chip and the second lower part surface of the interposer substrate, and
wherein the lower substrate comprises a lower wiring structure.

17. A semiconductor package comprising:
a lower substrate comprising a lower wiring structure;
a first lower semiconductor chip disposed on the lower substrate;
a second lower semiconductor chip disposed adjacent to the first lower semiconductor chip on the lower substrate and having a thickness thinner than that of the first lower semiconductor chip;
an interposer substrate disposed above the first lower semiconductor chip and the second lower semiconductor chip; and
a molding layer for covering the first lower semiconductor chip and the second lower semiconductor chip,
wherein the interposer substrate comprises:
a first lower part surface facing the first lower semiconductor chip and spaced apart from the lower substrate at a first interval; and
a second lower part surface facing the second lower semiconductor chip and spaced apart from the lower substrate at a second interval smaller than the first interval.

18. The semiconductor package of claim 17, wherein a difference between the first interval and the second interval corresponds to a difference between a height of an upper surface of the first lower semiconductor chip and a height of an upper surface of the second lower semiconductor chip.

19. The semiconductor package of claim 17, wherein the interposer substrate further comprises a stepped part formed between the first lower part surface and the second lower part surface.

20. The semiconductor package of claim 19, wherein the stepped part comprises a cross section of two or more stacked insulation layers.
